(19) United States
(12) Patent Application Publication
(10) Pub. No.: US 2008/0006835 A1
(43) Pub. Date: Jan. 10, 2008

(54) Photonic Band Gap Materials With Phosphors Incorporated

(75) Inventors: Cornelis Reinder Ronda, Aachen (DE); Holger Monch, Vaals (NL); Hans Nikol, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/572,239

(22) PCT Filed: Jul. 14, 2005
(86) PCT No.: PCT/IB05/52344

§ 371 Date: Jan. 17, 2007

(30) Foreign Application Priority Data
Jul. 22, 2004 (EP) 04103510.6

(51) Int. Cl. H01L 33/00

(52) U.S. Cl. 257/94; 257/98; 257/E33.001

(57) ABSTRACT

The present invention relates to the use of photonic band gap materials with phosphors incorporated. Photonic band gap materials play an important role for LEDs as light sources in applications where either a high radiance is desirable or LEDs are used in optical systems. The optical properties of current LEDs are such that the radiance is rather low and cannot be increased by standard means. It is an object of the invention to improve the radiance of light emitting devices by making use of photonic band gap materials with phosphors incorporated. According to the invention there is provided as structured material comprising a photonic structure that adjusts a range of photon frequencies, also referred to as photon density of states, in specific directions only, further comprising phosphor material having at least one emission mode for which the photon frequency is in the range adjusted by the photonic structure wherein the structured material has a symmetry lower than cubic such that the photonic structure adjusts the generation of photons emitted via said it least one emission mode of the phosphor material in less than three directions in this way increasing the radiance.

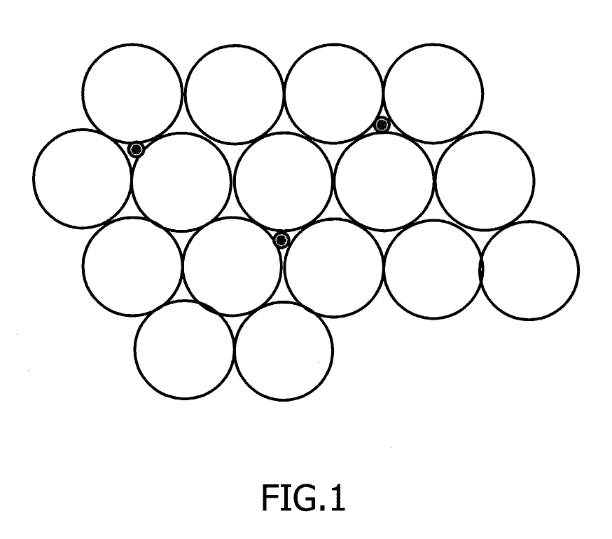

The present invention relates to the use of photonic band gap materials with phosphors incorporated.

Photonic band gap materials play an important role for LEDs (light emitting diodes) as light sources in applications where either a high radiance is desirable or LEDs are used in optical systems. The optical properties of current LEDs are such that the radiance is rather low and cannot be increased by standard means, in view of their etendue. Etendue E characterizes the ability of an optical system to accept light. It is a function of the area of the emitting source and the solid angle into which it propagates. Etendue therefore, is a limiting function of system throughput. Although LEDs offer high switching speeds, they emit light over a wide angle which makes them less suitable for optical systems. LEDs are made from so-called emissive materials that emit photons once they have been excited electrically or optically. Photonic band gap materials can be used to design a mirror for the emissive materials that reflects a selected wavelength region of light from one or more angles with high efficiency. Moreover, they can be integrated within the emissive layer to create a LED that emits light at a specific wavelength and direction.

The effect of LEDs suffering from a relatively low radiance can be explained as follows: The radiance L is given by the luminous flux φ divided by the etendue E. The etendue E, in turn, is given by the light generating area A multiplied by the solid angle Ω at which light leaves the device:
L=φ/E
E=A*Ω.

For light sources in thermodynamic equilibrium, etendue is conserved. This means that a reduction of the solid angle, e.g. by applying optical elements, goes hand in hand with an increase of the effective light generating area. So given the luminous flux φ for a LED in thermodynamic equilibrium there is no way of increasing the radiance L of a LED.

The low radiance of LEDs hampers or prevents LEDs from applications where high radiances are needed like in endoscopy or where LEDs are applied in optical systems to generate a specific light distribution like in car lamps. These deficiencies are illustrated by the following table.

TABLE 1

| Light source | Light density [10⁶cd/m²/sr] |
|---|---|
| Fluorescent lamp | 0.05 |
| LED | 1-10 |
| Halogen lamps | 20-30 |
| MPXL (micro power xenon light) | 100 |
| UHP (ultra high pressure) | 1000 |

In WO 01/69309 A2 there is disclosed a light emitting structure with photonic band gap transparent electrode structures. According to the description a conventional transparent electrode made of a semiconductor/metal-oxide, such as ITO (indium tin oxide), in a LCD (liquid crystal display) device is replaced by a transparent, multilayered electrode, or transparent stack, exhibiting a photonic band gap structure that transmits a visible range of wavelengths of the electromagnetic spectrum. According to a specific embodiment the substrate layer under the active layer is a semiconductor substrate layer made of a Silicon Carbide (SiC) composition.

WO 03/087441 A1 describes photonic materials that suppress a mode of photoemission. Preferably the materials are manufactured by assembling polystyrene spheres as a template for a photonic lattice and filling the gaps between the materials with a first material, eliminating the spheres and then filling in the spaces left by the spheres with a second material. Either material may be doped with a phosphor. Two important classes of luminescent phosphor are mentioned, namely Stokes phosphors, where the emitted light is of longer wavelength than the absorbed and anti-Stokes phosphors, which emit a light of a shorter wavelength than that absorbed.

It is an object of the invention to improve the radiance of light emitting devices by making use of photonic band gap materials with phosphors incorporated.

According to the invention there is provided a structured material comprising
a photonic structure that adjusts a range of photon frequencies, also referred to as photon density of states, in specific directions only and
phosphor material having at least one emission mode for which the photon frequency is in the range adjusted by the photonic structure, i.e. the photon density of states,

wherein the structured material has a symmetry lower than cubic such that the photonic structure adjusts the generation of photons emitted via said at least one emission mode of the phosphor material in less than three directions in this way increasing the radiance.

In a preferred embodiment the phosphor material is embedded in the photonic structure.

According to another embodiment the phosphor material is, at least in part, clad in the photonic structure.

The structured material preferably comprises reflective material arranged to adjust photons emitted via said at least one emission mode of the phosphor material.

In a further preferred embodiment the photonic structured comprises a periodic lattice.

According to the invention there is also provided a LED (light emitting diode) comprising a structured material according to one of the above-mentioned embodiments.

An essential feature of the present invention is therefore the application of substances incorporated in photonic band gap materials, which help creating units in which absorption and emission do not necessarily take place at the same wavelength anymore. Due to the (anti-)Stokes Shift, light is emitted in a spectral range where the luminescent material does not absorb. In this way thermodynamic equilibrium is kind of circumvented and consequently there is a way now to increase radiance by change of wavelength. As an effect the shortcomings of LEDs can now be resolved because light generation does not take place in thermal equilibrium. This, however, is also true in non photonic band gap materials and is not a specific feature of the invention.

The more important aspect of the invention is that the photonic band gap material can now be used to adjust optical emission of one or more luminescent materials incorporated in it, in one or more preferred directions by choosing a proper symmetry of the host photonic crystal, and to prohibit emission in other directions, in this way circumventing thermodynamic equilibrium. To this end, host photonic crystals with symmetry lower than cubic have to be chosen. As a result, the solid angle can be reduced strongly, decreasing the etendue and increasing the radiance and/or reducing the effective light emitting area according to above mentioned formulas.

Light, generated in LEDs, is emitted at a certain solid angle. In view of etendue conservation, this means that a reduction of the solid angle is accompanied by an increase of the effective light generating area. Photonic band gap materials can be designed in such a way, that light propagation can be suppressed in one or more directions in a certain wavelength region. Application of luminescent materials changes the wavelength of the radiation. According to a preferred embodiment a photonic band gap structure is employed which uses all the light emitted by an LED but emits it in one or two directions only. Using all the light emitted by an LED means absorption by a luminescent material in a spectral region in which light can propagate in the photonic band gap material in all directions.

The invention will now be illustrated by way of example with reference to the accompanying drawing.

The FIGURE shows a cross-section of a photonic crystal consisting of building blocks of dimensions in the order of the wavelength of light, represented by white circles, doped with much smaller luminescent moieties, which are represented by dark circles. The luminescent moieties have no influence on the periodicity of the photonic crystal. The luminescent particles should have a diameter of less than 500 nm.

1. A structured material comprising:
a photonic structure that adjusts a range of photon frequencies in specific directions only,
phosphor material having at least one emission mode for which the photon frequency is in the range adjusted by the photonic structure
wherein the structured material has a symmetry lower than cubic such that the photonic structure adjusts the generation of photons emitted via said at least one emission mode of the phosphor material in less than three directions.

2. A structured material as claimed in claim 1 wherein the phosphor material is embedded in the photonic structure.

3. A structured material as claimed in claim 1 wherein the phosphor material is, at least in part, clad in the photonic structure.

4. A structured material as claimed in claim 1 claims comprising reflective material arranged to adjust photons emitted via said at least one emission mode of the phosphor material.

5. A structured material as claimed in claim 1 wherein the photonic structure comprises a periodic lattice.

6. A LED (light emitting diode) device comprising structured material according to claim 1.
